(19) United States
(12) Patent Application Publication
(10) Pub. No.: US 2025/0267919 A1
(43) Pub. Date: Aug. 21, 2025

(54) APPARATUS FOR THE PRECISION ASSEMBLY OF SMALL PARTICLES

(71) Applicant: Research 42 LLC, Melbourne, FL (US)

(72) Inventor: Matthew J. BAUER, Melbourne, FL (US)

(21) Appl. No.: 19/056,842

(22) Filed: Feb. 19, 2025

Related U.S. Application Data
(60) Provisional application No. 63/555,148, filed on Feb. 19, 2024.

(51) Int. Cl. H10D 84/01; B82B 3/00; B82Y 40/00; H10D 30/43; H10D 62/83; H10D 84/82

(52) U.S. Cl. CPC H10D 84/0123; B82B 3/0014; B82B 3/0052; B82B 3/0066; B82Y 40/00; H10D 62/83; H10D 84/82; H10D 30/43

(57) ABSTRACT

A chamber and surrounding system for the assembly of high yielding, high density, accurately and deterministically placed discrete nano or microparticles or particle arrays are provided, where the positioning of the particles is maintained during a supercritical drying process. The nanoparticle assembly chamber is based upon the dielectrophoretic force generated AC electrodes patterned on a substrate and contacted with electrical feedthroughs, a secondary electrophoretic force generated by a DC electrode opposite the substrate to force particles from the bulk solution near the substrate surface to increase deposition rate, and a fluidic pump to flow solution containing nanoparticles over the substrate surface. The magnitude of the dielectrophoretic forces and electrophoretic force can be adjusted by the geometric parameters, the bias potential applied to the DC bias electrode, and the magnitude of the AC electric field applied to the substrate electrodes.

### CROSS-REFERENCE TO RELATED APPLICATION

The present application claims the benefit of U.S. Provisional Application Ser. No. 63/555,148, filed Feb. 19, 2024, which is hereby incorporated by reference herein in its entirety, including any figures, tables, or drawings.

### BACKGROUND OF THE INVENTION

Many unique electrical, semiconducting, photonic, mechanical, thermal, and magnetic material phenomena exist within the areas of nanotechnology and microelectronics for creating useful devices. Top-down assembly approaches, such as those exemplified in the semiconductor industry, represent the current art in high-volume manufacturing of micro and nanoscale devices. Well-known devices manufactured in these facilities include the transistor, MEMS devices, displays, and silicon photonics devices. This top-down approach has enjoyed profound commercial success fabricating precision micro and nano-sized features. These features typically form as a result of modifying bulk materials, such as semiconductor wafers.

The manufacturing processes rely on a limited set of well-developed material systems and processes. Starting materials are most often in high purity, defect-free monocrystalline forms such as silicon and compound semiconductors, each having their associated compatible material sets to complete device processing. Common processes are used such as photo lithographic patterning, etching, deposition, ion implantation and diffusion where deposition from solutions and vapors composed of simple atoms, ions, and molecules achieve bulk material deposits in a layered fashion. Molecular beam epitaxy has expanded the material sets beyond bulk deposition and can achieve monocrystalline growth, but material sets are still limited compared to the number of nanomaterials conceived. Reasons for this limitation include: the material lattice of the material to be deposited must be compatible with forming a single crystal with the underlying material, strain induced by the epitaxial layer and subsequent layers must be minimal and well controlled, the processing temperature of the layers must be compatible.

Bottom-up fabrication in contrast involves assembling discrete nanostructures formed off substrate into devices. Some common bottom-up micro-assembly and nano-assembly processes include ink-jet printing for micropatterning or direct manipulation of microparticles using optical tweezers or equipment such as the scanning tunneling microscope that can be used to position individual atoms. These other techniques suffer from insufficient nanoscale precision or slow manufacturing rates for mass-production of devices or both.

Many applications require a bottom-up approach for assembling discrete micro and nanoparticles into precise patterns at high volumes. In these cases, the desirable material properties needed to achieve intended device functionality is attributed to the inherent particle and its unique properties as a particle. The top-down methods can be ineffective if (1) the only known methods of synthesizing the required particles cannot be performed directly on substrate (2) the orientation or location of particles cannot be controlled while synthesizing them on substrate (3) the processing temperature or environment required to synthesize the nanoparticle is incompatible with the underlying layers of the device (4) the as synthesized nanoparticles require additional purification steps to achieve sufficient purity for device fabrication. A specific example of a particle which is commercially important for photonic applications but cannot be fabricated on substrate is metallodielectric colloidal core shell particles comprising a silica center and gold shell, and more generally all core shell spherical particles. Given their unique geometry these particles can only be formed in solution-based processes such as precipitation or electro-spraying. Particles which can be synthesized on substrate but only with uncontrollable patterning include those created by solution-liquid-solid (SLS) or vapor-liquid-solid (VLS) synthesis. These include various III-V, II-IV, II-VI, and other semiconducting wires as well as carbon nanotubes. However, as fabricated these wires may be impure and are randomly dispersed in a vertical orientation making it impossible to deterministically create circuits. Many of the VLS methods are performed at high temperatures which may be incompatible with other materials in the device. Many particles such as carbon nanotubes require purification processes before they can reach sufficient purity for incorporation into very large-scale interconnect (VLSI) devices.

Semiconducting carbon nanotubes are a notably important example of a particle for the realization of next generation microelectronics devices. Billions of these nanotubes must be positioned and deposited at the nanoscale to form modern complex integrated circuits such as systems-on-chip (SoC). For the semiconductor application in particular, there are many emerging technologies seeking to extend semiconductor scaling beyond CMOS capabilities with improved performance metrics such as reduced energy consumption, higher speeds, higher functional density, and increased material and device heterogeneity. Many of the most promising candidates require methods of nanoparticle assembly. Other application domains reliant on progress in nanotechnology include sensing, energy, communication, pharmaceuticals and healthcare. Therefore, there is wide appeal for a suitable manufacturing technology that can enable the transition from academic and corporate research discoveries in nanotechnology and microelectronics to commercialization. However, many significant discoveries remain hampered without equipment able to assemble discrete particles en masse with high yields, high selectivity, and full coverage onto a substrate.

A number of issues inhibit robust bottom-up nanoparticle assembly on a commercial scale. First is the ability to source high purity starting materials where only the desired particle species is present. For semiconductors with 1 billion transistors per chip for instance, less than 1 ppb impurities or 99.9999999% purity source materials must be attained to achieve viable yields. If source materials cannot be attained with the desired purity, the process must be able to selectively assemble only the desired particles having the correct properties. Second, the particles must be placed accurately on ever diminishing nanometer scales. Although several deposition techniques exist, achieving proper orientation and single particle placement without duplicates remains a challenge. Third, the assembly process must be able to provide full coverage so as to be able to place all the particles required to complete assembly over the entire workpiece as intended. The ability to concentrate particles near the workpiece surface without causing interfering particle-particles interactions like agglomeration becomes important to realize full coverage. Fourth, once placed, the particles must remain in position during subsequent processing. Particle assembly often relies on depositing particles from liquid solutions and removal of the liquid after drying results in strong surface tension effects and imbalanced forces at the drying liquid-workpiece interface which moves particles out of position. Low surface tension fluids can still cause particle placement disturbances due to surface tension imbalance while freeze drying and sublimation drying require liquid-to-solid phase changes to first take place before sublimation and the liquid-solid associated dimensional changes also distort.

### BRIEF SUMMARY OF THE INVENTION

Embodiments of the subject invention provide systems and methods for first selectively depositing small microscale or nanoscale particles from a dielectric fluid mixture within a chamber onto a workpiece or substrate placed inside the chamber with electrical connections. The fluid mixture comprises inhomogeneous small particles in suspension having morphologies being either spherical (0D) or rods and tubes (1D), although other more complex shapes are also viable (ellipsoid, torus, bean-shaped or peanut-shaped, bent, branched, etc.). Based on dielectric properties, certain particles are selectively attracted to precise locations onto a substrate that coincide with the location of substrate electrodes where the attraction force is caused by the generation of an electric AC field emanating from these substrate electrodes locally interacting with the particles in solution with the dielectrophoretic force. Second, using additional chamber electrodes, a DC field is applied across the fluid and substrate to create electrophoretic forces on the particles to concentrate them near the substrate surface. Third, the chamber is temperature and pressure controlled to introduce a zero surface-tension supercritical fluid inside the chamber to rinse the particle solution and allow drying without incurring particle placement distortion effects.

To enable the desired particles to be attracted, aligned and placed, the substrate electrodes' AC fields locally extend into the solution mixture a short distance to interact with potentially inhomogeneous and polydisperse particles suspended in the dielectric fluid. The AC electric field instantaneously polarizes particles suspended in solution near the electrodes depending on the relative permittivity and conductivity of both the solvent and particles. In particles that polarize and experience positive dielectrophoresis the particles are forced toward areas of high electric field gradient, and particles that experience negative dielectrophoresis that are forced toward areas of low electric field gradient. The direction and magnitude of the dielectrophoretic force depends upon the relative permittivities and conductivities of the solvent and particle, electric field gradient magnitude, and AC frequency of the field according to equation 1.

$$< {F}_{D E P} > = 2 π {r}^{3} {ε}_{m} R e \{ \frac{{ε}_{p}^{*} - {ε}_{m}^{*}}{{ε}_{p}^{*} + 2 {ε}_{m}^{*}} \} ∇ {\vert {\vec{E}}_{r m s} \vert}^{2} \qquad Eq . 1$$

Where <F_{DEP}> is the dielectrophoretic force, r is the particles radius, εₘ* is the mediums permittivity and εₚ* is the particle's permittivity. The complex dielectric constant is given by

$${ε}^{*} = ε + \frac{i σ}{ω} \qquad Eq . 2$$

Where σ is the conductivity of the particle or medium, ε is the dielectric constant, w is the field angular frequency, and i is the imaginary unit.

The AC field extents are relative to several multiples of the particle size and electrode spacing and interact with particles in the fluid directly adjacent to and in contact with the substrate. In some embodiments the AC field is tuned by frequency to establish an attractive dielectrophoretic force to only particles with the desired dielectric properties relative to the dielectric properties of the fluid medium. Furthermore, particles lacking the desired dielectric properties are repelled by AC fields enabling high purity deposition from lower purity mixtures. Individual and localized AC fields are generated by each electrode pair in order to selectively couple (trap), align, and attract individual particles that leads to complete deposition of a particle onto a specific energized electrode pair. The strength of the electric field and therefore its effective extents permeating into the fluid is controlled by AC signal amplitude. Once a particle is placed across the electrode, the AC field is then inherently altered by the contacting particle so as not to attract other particles avoiding undesired duplicate deposition onto the same electrode. As the selected particles in the local AC field migrate toward the substrate the region of fluid adjacent to the substrate becomes depleted and must be replenished.

Due to the short-range effect of the dielectrophoretic force on particles in solution, some AC electrical assembly approaches have incorporated microfluidic channels to force the entirety of the solution flowing over the substrate, and thus bring the particles closer to the surface and within range of the dielectrophoretic force. However, there are several limitations and costs to this approach. Firstly, the area of deposition when using a flexible microfluidic channel such as the commonly used polydimethylsiloxane (PDMS) is limited as low aspect ratio channels tend to collapse. Secondly, as the electrode spacing becomes increasingly small, such as the spacing required to assemble dense arrays of small nanoparticles such as carbon nanotubes, the region where particles can be pulled from the bulk solution towards the electrodes by the dielectrophoretic force decreases limiting the effectiveness of the channel. Lastly there are two main manufacturability issues associated with this approach, contamination and throughput. Generally, in wafer-level device fabrication, direct contact with wafers is discouraged, as it can introduce undesirable levels of contamination. However, an exception is chemical mechanical planarization (CMP), where the surface is finely polished, making it easier to clean.

Attaching and detaching microfluidic channels on each die of a wafer would likely lead to very low device yields. From a throughput perspective, to perform assembly the microfluidic channel would first need to be cast in PDMS over a template wafer with thick electroplated ridges. Following this, plasma treatment would be required for a sufficient seal to the assembly wafer, the channels would then need to be placed on the assembly wafer, and fluid runs would need to be connected to the microfluidic channel. Following this, fluid would be pumped through the channels while assembly occurs. Drying would then need to take place, and the channels would then need to be detached and reattached at the next die. Eventually the PDMS surface would become too contaminated and new microfluidic channels would need to be fabricated. Microfluidic channels occasionally move relative to the substrate during the process due to a pressure imbalance or slight movement of the tubes leading to the loss of microfluidic channels' seals, which is also a significant issue with this approach. All of this makes the practice of utilizing microfluidic channels to force particles toward the substrate for AC electrical assembly a difficult process to integrate into a high-volume manufacturing process. In order to force particles towards the surface of the substrate where AC electrical assembly can occur, in embodiments of the subject invention a combination of electrophoresis and dielectrophoretic force-based assembly is provided. The electrophoretic force, in contrast to the dielectrophoretic force, is a DC electric field-based effect. When a particle is suspended in solution it may become charged, either positively or negatively, due to its surface terminated functional groups and the pH of the solution. An added benefit to modifying the particle surface and solution as a high magnitude surface potential leads to a high magnitude zeta potential, or potential between the near particle region and bulk solution, which acts as a repulsive force between nearby particles keeping them from agglomerating and falling out of solution. When a charged particle is suspended in solution within an electric field it is moved in proportion to the electric field with an electrophoretic velocity as described below.

$${v}_{e p} = {μ}_{e p} E \qquad Eq . 3$$

Where μₑₚ is the particles electrophoretic mobility and E is the magnitude of the applied electric field. The electrophoretic mobility is proportional to the particle's charge as mentioned previously according to the equation.

$${μ}_{e p} = \frac{q}{6 πη r} \qquad Eq . 4$$

Where q is the particle's charge, η is the solution's viscosity, and r is the particle's radius.

While the dielectrophoretic force resulting from the AC voltage applied to electrodes patterned on the substrate drops off rapidly with distance, the DC electric field within parallel plate electrodes is approximately constant between electrodes. Since the electrophoretic force is proportional with the electric field, a planar DC electrode configuration can be utilized in addition to the electrodes needed for AC assembly to move particles from the bulk of the solution near the substrate surface. Certain embodiments provide for a DC field across the substrate and solution to create electrophoretic forces on the particles causing motion of the particles toward the substrate. The bias electrode, or electrodes, may be of multiple geometries wherein the simplest is a planar electrode of the same size as the substrate. Alternatives may comprise multiple DC bias electrodes perpendicular to the flow of the solution with different bias potentials. One approach is to optimize not for uniform electric field but for uniform particle density along the surface of the substrate using finite element analysis to model and predict the particulate flow within the fluid. The purpose of the DC bias electrode is to be biased with a tunable voltage with respect to the average potential experienced by the AC electrodes. This effect can be augmented by holding the stage underlying the substrate with a DC voltage matching the average of the time varying voltage applied to the substrate.

In embodiments there are fluidic pumps below the substrate holder and substrate that move fluid through channels up and around the substrate, flowing solution over the substrate, and back down to the location of the pumps. The pumping mechanism may vary depending upon the solution and particles being deposited. However, a simple method for moving fluid continuously that does not need to move through a high-pressure differential, and that in a preferred embodiment here are rotors with blades attached. The flow near the rotors below the substrate is turbulent, assisting with the dispersion of particles in solution, while the flow over the substrate will largely be laminar. The flow of the fluid containing the particles induces the movement of particles through the drag force. The drag equation is given below:

$${F}_{D} = \frac{1}{2} ρ {v}^{2} {C}_{D} A \qquad Eq . 5$$

Where F_{D} is the drag force, [symbol] is the density of the fluid, ν is the velocity of the particle with respect to the fluid, A is the cross-sectional area of the particle, and C_{D} is the drag coefficient. Importantly the velocity is the relative velocity of the particle with respect to the fluid, thus a stationary particle in a moving fluid will experience the same drag force as a moving particle in a stationary fluid if the difference in velocity between the fluid and particle is the same magnitude.

With this laminar flow of particles over the substrate between a large parallel electrode and repeating sets of substrate AC electrodes with bias acting similarly to a planar DC counter electrode on average the particles in the bulk of the substrate experience an electrophoretic force toward the substrate surface. Then when close to the substrate the dielectrophoretic force preferentially assembles particles experiencing a positive dielectrophoretic force while repelling any potential impurities, if any, that exhibit a negative dielectrophoretic force due to differences in their relative permittivity and conductivity.

Other beneficial forces acting on the particles during assembly include dipole-dipole interactions inhibiting clustering of particles on the same electrode as nearby dipoles repel each other, and electrostatic forces that predominantly hold the particles in place across the substrate electrodes after they have been assembled. Forces that can disrupt assembly include Brownian motion, convective motion generated by joule heating by the AC electrodes, and most notably surface tension disrupting the assembly during the drying process. This surface tension becomes increasingly problematic with smaller and smaller nanoparticle size and smaller alignment tolerances. Whereas microparticles assembled across long parallel electrodes may maintain sufficient positioning during a normal drying process, particles below 300 nm or so experience major disruptions often ending not near the AC electrodes in some instances, although depending upon the drying pattern and surface roughness some particles may maintain their position.

To eliminate or minimize the surface tension during drying the chamber is designed for high pressure tolerances, for example 3000 PSI, with gas inlets and compressor to allow for novel in-situ supercritical drying. The in-situ nature of the drying is significant, as with small nanoparticles the removal of the AC electric field allows the assembled particles to be disrupted by Brownian motion in the absence of the electrostatic forces holding them in place.

In a preferred embodiment, solution will be drained from the chamber until slightly above the substrate surface while maintaining an AC electric field. Following this a pressurized gas that can form a supercritical fluid with the assembly mixture is introduced and the substrate is heated to slowly move the solution above the substrate from liquid to supercritical phase, an approximately zero surface tension phase transition. Then pressure is slowly released from the chamber to drive a supercritical to gaseous phase transition, again with minimal to no surface tension until the wafer is dry. Any remaining excess solution captured off-wafer is then drained, and the substrate can be removed. In one embodiment a largely methanol based liquid assembly solution is used, and pressurized gaseous carbon dioxide is introduced to form a supercritical/gaseous methanol/carbon dioxide mixture.

Embodiments can satisfy four conditions in conjunction: (1) Exclusively selecting a primary type of particle over other non-primary particles in a fluid suspension for deposition onto a workpiece using AC fields and the dielectrophoretic force, (2) depositing each selected particle in alignment across a corresponding single pre-patterned micro or nano-sized electrode pair on the substrate, (3) gentle replenishment of particles from the bulk solution to the localized AC fields near the substrate by causing the migration of particles through the solution toward the substrate using electrophoresis to provide full deposition coverage of particles without excessive solution concentration, and (4) partial draining of the particle and fluid solution followed by flushing using a pure fluid and subsequent repeated rinsing and drying of the wafer with deposited particles using a supercritical fluid such as carbon dioxide.

### BRIEF DESCRIPTION OF THE DRAWINGS

As used herein, the terms “a,” “an,” “the” and similar terms used in the context of the present invention are to be construed to cover both the singular and plural unless otherwise indicated herein or clearly contradicted by the context. Thus, for example, reference to “an arm” or “a hole” should be construed to cover or encompass both a singular arm or a singular hole and a plurality of arms and a plurality of holes, unless indicated otherwise or clearly contradicted by the context.

As used herein, the terms “about” and “approximately” shall generally mean an acceptable degree of error for the quantity measured given the nature or precision of the measurements. Exemplary degrees of error are within 20 percent (%), typically, within 10%, and more typically, within 5% of a given value or range of values.

As used herein, the term “and/or” should be understood to mean “either or both” of the features so conjoined, i.e., elements that are conjunctively present in some cases and disjunctively present in other cases.

As used herein, the terms “comprising”, “consisting of” and “consisting essentially of” are defined according to their standard meaning. The terms may be substituted for one another herein in order to attach the specific meaning associated with each term.

As used herein, the term “or” should be understood to have the same meaning as “and/or” as defined above. For example, when separating a listing of items, “and/or” or “or” shall be interpreted as being inclusive, i.e., the inclusion of at least one, but also including more than one of a number of items, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.”

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 is an illustrative diagram of the chamber interior showing substrate and supporting components to generate fluidic drag forces, electrophoretic driving forces, and dielectrophoretic driving forces to enable particle assembly on fine pitched electrodes without contacting the surface of the wafer or requiring microfluidic channels, according to an embodiment of the subject invention.

FIG. 2 is an illustrative diagram showing the predominant forces acting upon a particle further away from the electrodes than would be possible to achieve assembly from with AC electrical assembly only as the particle is in a region of low electric field gradient, according to an embodiment of the subject invention.

FIG. 3 is an illustrative diagram showing the charge induced on a particle near the surface of the electrode under positive dielectrophoretic force driven assembly. Within this region the electrophoretic force and fluidic drag forces are low in comparison to the dielectrophoretic force, according to an embodiment of the subject invention.

FIG. 4 is an illustrative diagram of the surrounding chamber and fluid and pressure management required to introduce and flow particle containing solution and manage supercritical drying through control of the chamber pressure and introduction and removal of compressed gas, according to an embodiment of the subject invention.

FIG. 5 is a larger chamber system view showing the analog and control electronics along with fluid tank, pump, and scrubber system to treat outlet gas, according to an embodiment of the subject invention.

FIG. 6 is a process flow chart outlining the steps to perform electrical assembly utilizing the chamber, according to an embodiment of the subject invention.

FIG. 7 is an illustration showing the drying process, according to an embodiment of the subject invention.

FIG. 8 shows geometry for the 2D finite element analysis of electric field and electric field gradient driving forces of particles in solution, according to an embodiment of the subject invention.

FIG. 9 shows finite element analysis of electric field norm vs distance with bias electrode, according to an embodiment of the subject invention.

FIG. 10 shows finite element analysis of electric field gradient with bias electrode, according to an embodiment of the subject invention.

FIG. 11 shows finite element analysis of electric field norm vs distance with bias electrode along a 1D line, according to an embodiment of the subject invention.

FIG. 12 shows finite element analysis of electric field gradient with bias electrode along a 1D line, according to an embodiment of the subject invention.

FIG. 13 shows finite element analysis of electric field vs distance along 1D cut line of FIG. 8 with and without bias electrode along a 1D line, according to an embodiment of the subject invention.

FIG. 14 shows finite element analysis of electric field gradient vs distance along 1D cut line of FIG. 8 with and without bias electrode, according to an embodiment of the subject invention.

### DETAILED DISCLOSURE OF THE INVENTION

Embodiments of the subject invention are directed to an apparatus for the precision assembly of small particles.

To create an electrical assembly chamber utilizing the electrophoretic, dielectrophoretic, and fluidic drag forces to assemble dense nanoparticle arrays, with precisely and deterministically defined nanoparticle positions, the electric fields and fluid motion need to be well controlled around the assembly regions.

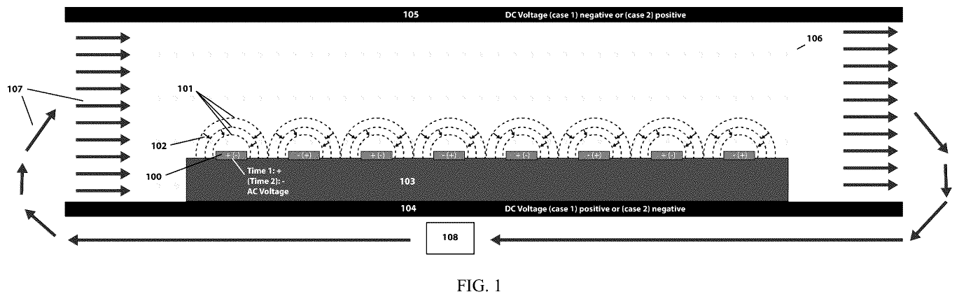

Referring to FIG. 1, the areas surrounding the assembly region above and around the substrate within the chamber interior are shown. Alternating current/voltage (AC) electrodes 100 are configured to generate electric field gradients for the dielectrophoretic force to act upon particles suspended in solution. Constant electric field gradient lines are illustrated in 101 with the direction of the positive dielectrophoretic force as described in Eq. 1 shown in 102. The substrate 103 upon which the AC electrodes are patterned and direct the assembly has in its preferred embodiment through substrate vias to connect the top electrodes to electrical feedthroughs in the substrate holder 104 to supply the AC signal. While topside electrical connections can also be used this will increase the likelihood of contamination reducing yield and turbulent flow of the particle solution over the substrate. This substrate holder 104 may also be subject to a DC bias potential in addition to average bias potential on the AC electrodes 100. A DC biased counter-electrode 105 is used to generate an electric field between it and the AC electrodes 100 and substrate holder 104 which will be kept at a different average potential. This will impart a tunable electrophoretic force, depending upon the magnitude and sign of the applied potential difference, upon particles in the bulk solution according to Eq. 3. The direction of the electrophoretic force 106 generated between the bias electrode and substrate during assembly will move particles from the bulk solution toward the substrate surface to be assembled with the closer range dielectrophoretic forces. The flow of the solution 107 generated by a pump that may be as simple as a rotor with blades attached 108 forces particles in solution continuously over the substrate's surface.

The pump may be either an internal pump disposed in the chamber, or an external pump disposed out of the chamber. The pump may function to fill/drain and/or maintain the flow.

In one embodiment, a sonicator is utilized to maintain nanoparticle dispersion.

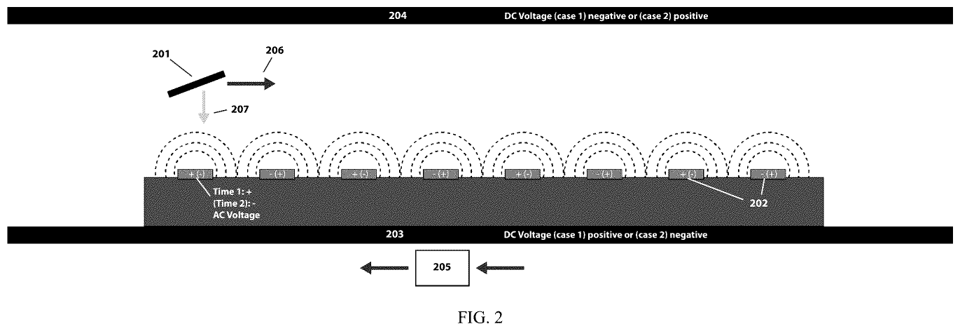

FIG. 2 illustrates a particle 201 in the bulk solution and forces acting upon the particle. Due to the fluid motion driven from the pump 205, the particle experiences a drag force 206 along a direction that is in parallel to the substrate. The DC field across the substrate electrode 203 and counter-electrode 204 creates an electrophoretic force 207 applying on the particles toward the substrate surface.

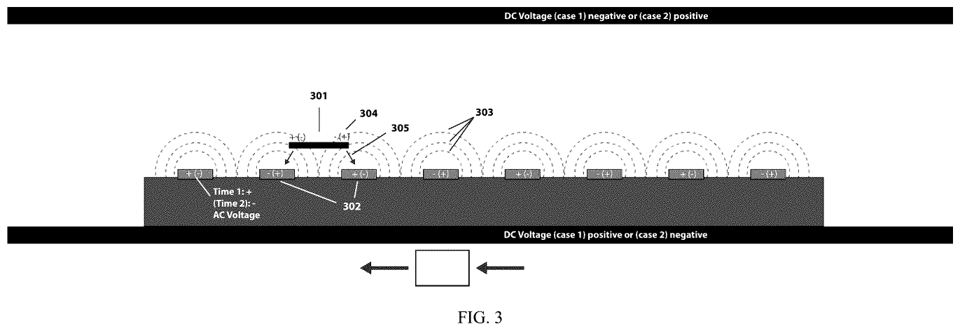

As shown in FIG. 3, forces act on a particle 301 near the substrate surface. In this region the dielectrophoretic force is relatively much stronger than the electrophoretic force and drag force upon the particle. AC electrodes 302 are labeled with their potential at time 1 not in parenthesis and their potential at time 2 within parenthesis. Similarly, the polarization of the ends of the particle 304 are labeled with the polarity at time 1 not in parenthesis and time 2 polarization within parenthesis. Areas of equal electric field gradient 303 extend radially from each electrode. The positive dielectrophoretic force direction 305 pulls the particles across the adjacent electrodes. This allows for type-selective and position-deterministic patterning of nanoparticles and microparticles fabricated off substrate onto the surface of the substrate based upon the electrodes 302 patterned via photolithography.

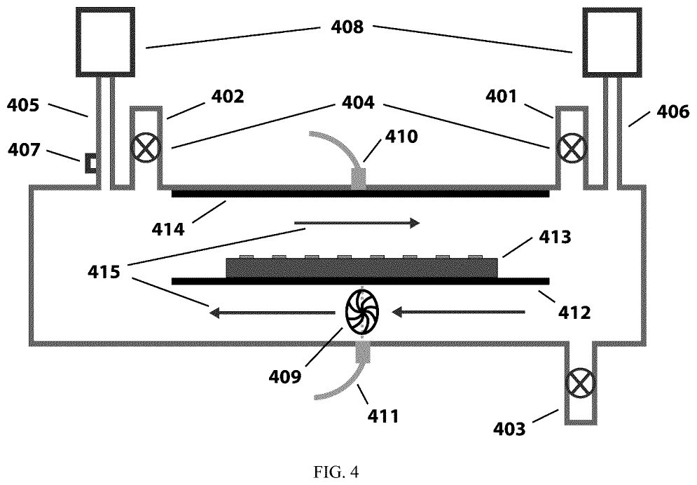

Referring to FIG. 4, some of the periphery of the chamber showing inlets and outlets for the nanoparticle containing solution and gas for supercritical drying are shown. The nanoparticle containing solution inlet 402 and solution fill outlet 401 are used for initial chamber filling. Liquid valves 404 control the flow of the fluid. Both are located at the top of the chamber to inhibit gas from being trapped before the assembly process. The particle solution drain 403 is utilized later during the drying process. The gas inlet 405 and outlet 406 regulators 408 are used to induce supercritical phase transition after the solution level is lowered to slightly above the level of the substrate to remove the solution from the surface of the substrate post assembly. Due to the high pressure required to achieve a supercritical phase transition an emergency overpressure valve 407 should be included for safety. During assembly when the liquid/nanoparticle phase fills the chamber, and all valves are closed a pump 409 induces nanoparticle and fluid motion 415 around the chamber and over the substrate. An electric potential difference between the bias electrode 414 with respect to both the substrate holder 412 and substrate 413 creates the electrophoretic force moving particles near the substrate surface. The electric potential to the bias electrode is provided by an electric feedthrough 410. Another electrical feedthrough 411 provides power to the fluid pump 409, the substrate DC electrode 412 and the AC electrodes on the substrate 413.

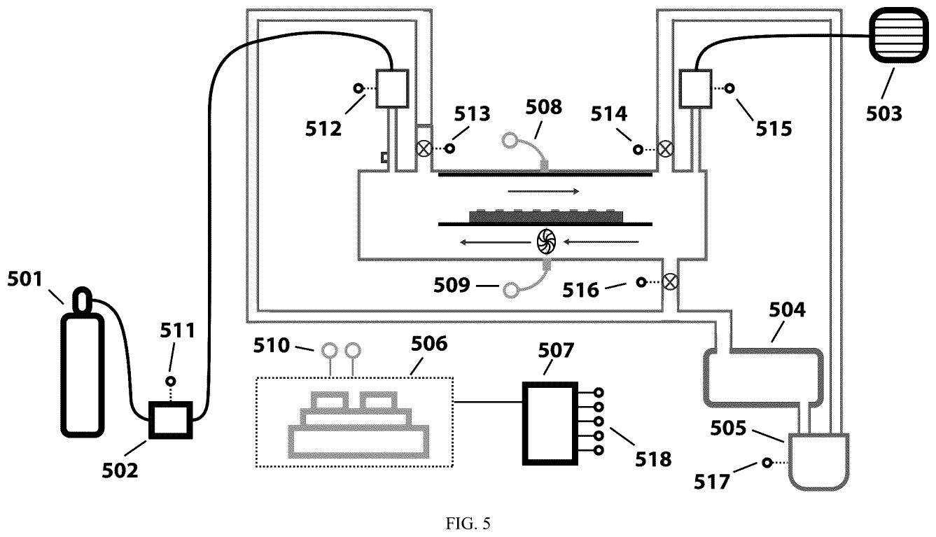

FIG. 5 shows a system level view of the components surrounding the main chamber. The gas cylinder 501 with compressor 502 enables the introduction of high-pressure gas to form the supercritical phase required for drying with minimal to no surface tension. The gaseous outlet is routed to a scrubber 503 in the preferred embodiment as it aids in safety depending upon the gas, liquid, and nano/micro particles used in assembly. A tank 504 which may be exposed to agitation such as a stirring mechanism to promote dispersion holds the nanoparticle/liquid solution used in assembly. This solution is introduced into the chamber with a pump 505 which may be, but not limited to, a peristaltic pump. The AC and DC electric fields used to control the electrophoretic and dielectrophoretic forces experienced by the particles under assembly are provided by a set of analog control equipment 506 automated by a PC or microcontroller 507. The outlets of the analog equipment 510 connect to the bias electrode feedthrough 508 and substrate feedthrough 509. The PC or microcontroller 507 has I/O 518 to control the compressor 511, input regulator 512, output regulator 515, solution inlet valve 513, solution fill outlet valve 514, solution drain valve 516, and the liquid/nanoparticle pump 517.

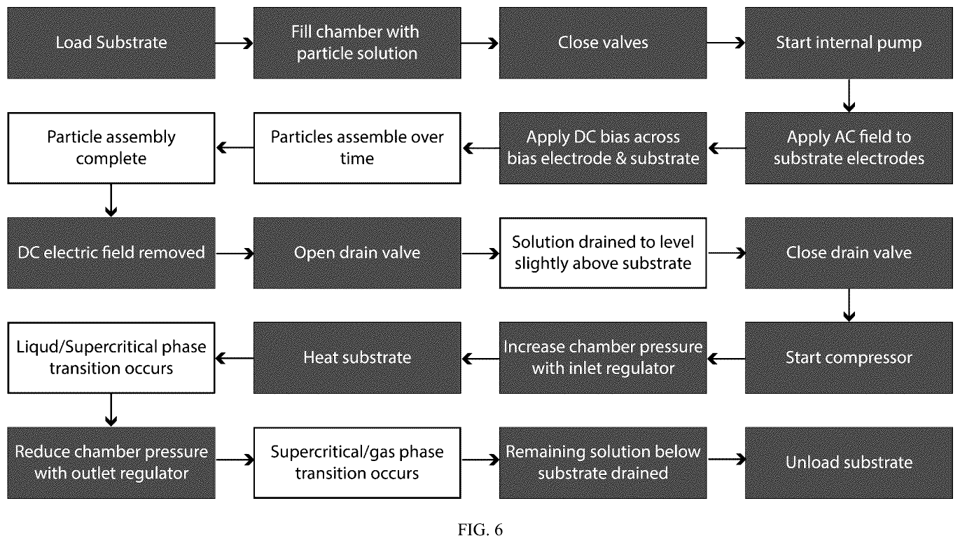

FIG. 6 shows the high-level flow chart for chamber operation. Within the flow chart changes to the chambers state are given in the filled rectangles, and events that happen as a result of previous actions are given in unfilled rectangles. The drying illustration is given in FIG. 7. The illustration is given mid process where the liquid to supercritical transition is taking place. Prior to the state shown the liquid level is lowered to a level 701 slightly above the substrate 702 surface. Then the liquid phase 703 is converted to a supercritical phase 704 through pressure applied by the compressor and regulator valves and heating the substrate. Heating may occur by a mechanism as simple as induction heating elements in the substrate holder. Depending upon the kinetics of the optimal pressure and heating operation and current time observed within this step there may be a gaseous phase 705 existing above the supercritical phase. Once the liquid phase level 706 is below the substrate pressure will be relieved with the outlet regulator to induce a phase change of the supercritical solution to gas down to a level 706 below the substrate. After pressure is relieved the remainder of the solution in the chamber will be drained and the substrate unloaded.

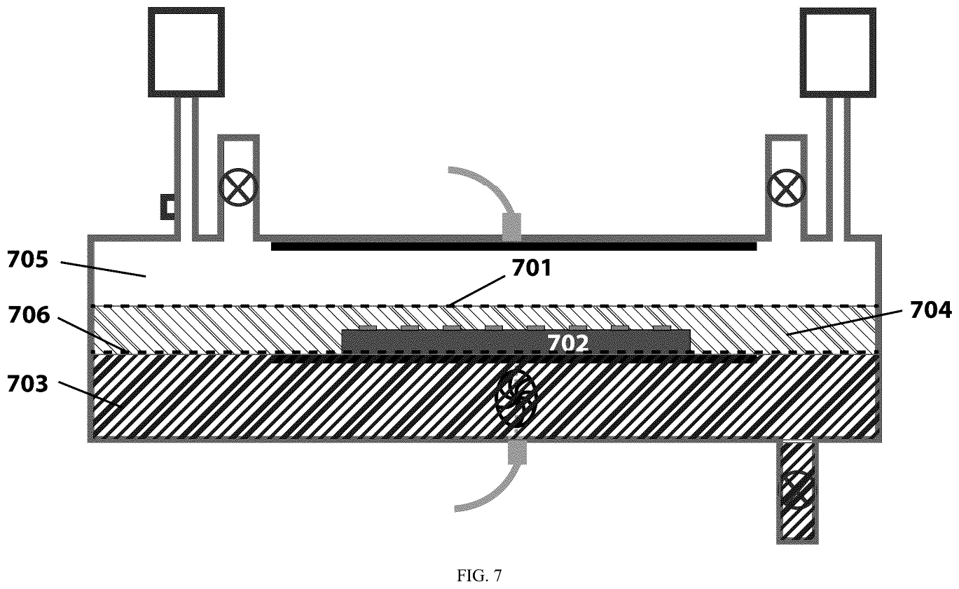

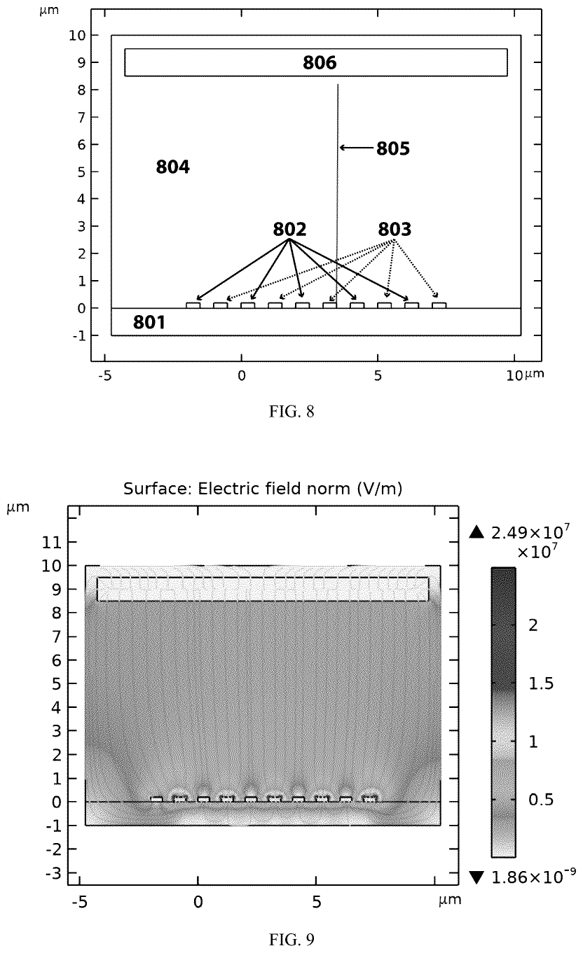

To validate the unique combination of electrophoretic forces and dielectrophoretic forces to assemble nanoparticles and microparticles without the use of microfluidic channels a finite element simulation is performed. To minimize computational intensity, and since further optimization will be needed, the length scales may differ between the simulated structure and final embodiment, however the qualitative conclusions from the finite element analysis will still hold. Geometry is defined for finite element simulation as illustrated in FIG. 8. The finite element analysis is performed at a single time t1 and not over a continuous time frame although time variant simulations and simulations including particle and fluid flow motion will inform the future optimal design, although these are computationally costly. The substrate 801 is modeled as quartz, although may be replaced with silicon, silicon carbide, gallium arsenide, or other material with or without an oxide layer. One set of electrodes 802 are simulated as aluminum with voltage −2.5V at time t1 to simulate the point in time in which the AC applied field will create a peak negative potential at these electrodes. The electrodes 803 are also modeled as experiencing a peak positive voltage 2.5V at time t1 to simulate the point in time in which the AC applied field will create a peak positive potential at these electrodes. The solution 804 is simulated as liquid methanol. The bias electrode 806 is modeled as aluminum with a bias potential of −40 V in the simulations with a bias electrode. In the simulations without a bias potential this bias electrode geometry is removed. The cut line 805 shows the axis along the 1D plots for electric field and electric field gradient are created. This line is kept in a constant location across all simulations.

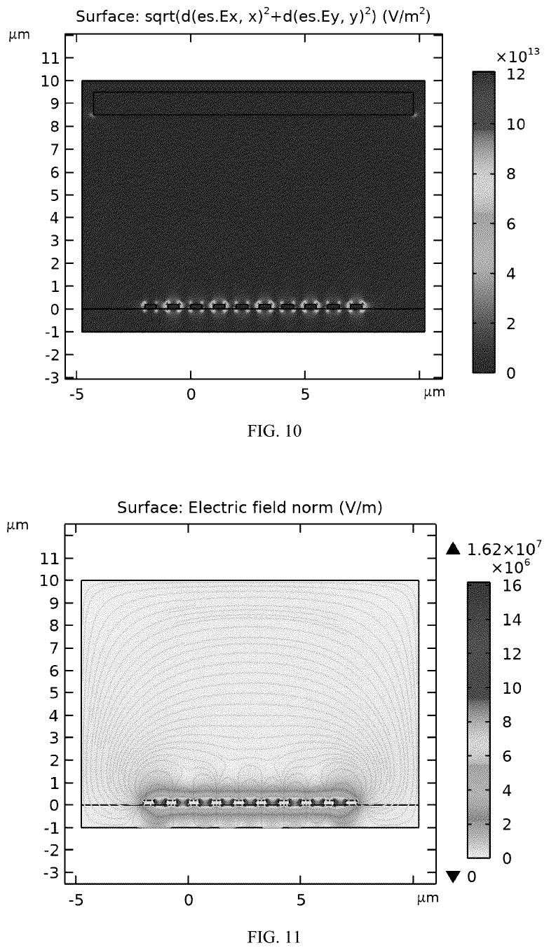

FIG. 9 illustrates the electric field norm results of the 2D finite element simulation with the bias electrode and FIG. 10 illustrates the electric field gradient magnitude results. Note that a particle suspended in solution will experience an electrophoretic force in proportion to the electric field gradient and that the electric field gradient is relatively uniform between the bias electrode and substrate. There are some differences in the negative and positive AC electrodes, however, averaged over time (AC fields utilized in dielectrophoretic based assembly are usually on the order of kHz to MHz) the field will become more uniform. This uniformity indicates that particles can be reliably moved from bulk solution toward the substrate with the electrophoretic force. As shown in FIG. 10, the electric field gradient decreases rapidly at points further out into the substrate. As the positive dielectrophoretic force moves particles from regions of low electric field gradient to regions with high electric field gradient in proportion to the strength of the field gradient this shows that the dielectrophoretic force will be relatively weak in the solution bulk but very strong near the substrate surface. Thus, the particle density near the surface can be tuned by the DC potential on the counter-electrode independently of the capture forces due to dielectrophoresis near the electrodes tuned by the AC field across the substrate electrodes.

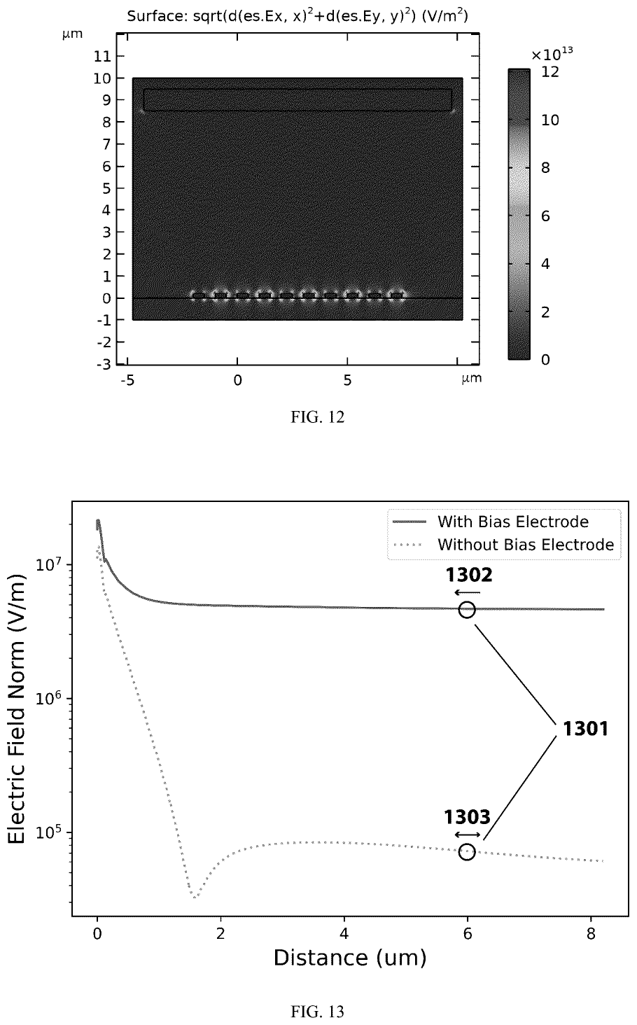

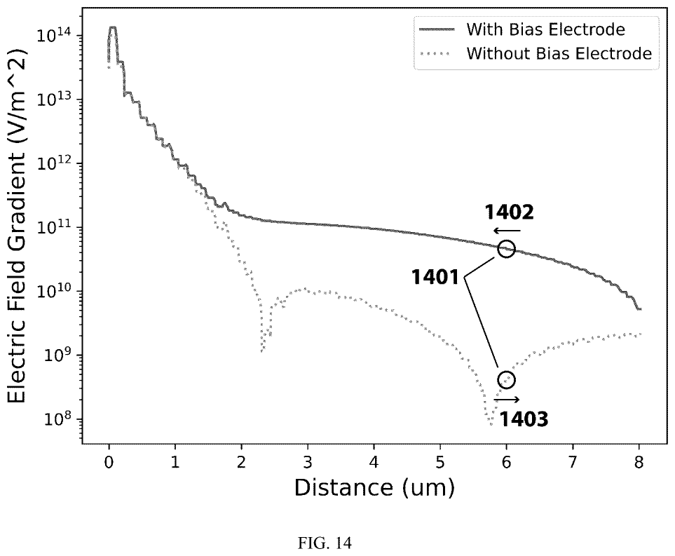

These results can be contrasted to the finite element simulation without bias electrodes, FIG. 11 for electric field norm and FIG. 12 shows finite element analysis of electric field gradient magnitude. In FIG. 11, the electric field norm in the no bias electrode configuration falls off quickly into solution. Moreover, the time average electric field in solution will be about 0. The 2D illustration of the electric field gradient shows that the electric field gradient still does not extend far into the solution at high magnitude. As such particle concentration will not be increased locally at the substrate surface inhibiting high coverage patterning over reasonable timeframes.

Comparing both geometries side by side along their 1D cut lines provides additional clarity and insights into the effect of these geometries on the forces experienced by a particle in solution further away and closer to the substrate. In each 1D cut line plot the reference distance, 0 μm, represents the location of the substrate electrode and the line extends into the bulk solution. The plots in FIG. 13 show the electric field norm vs. distance into the bulk solution at time t1. The location of a theoretical particle 1301 is considered for illustrative purposes. The electric field with bias electrode is significantly higher at all points and in the particle location 1302 the nano/microparticle will experience a strong electrophoretic force toward the substrate. While at a later time, t2, this force will be slightly weaker; it will be in the same direction as the bias electrode will still be at a lower potential −40 V than the substrate electrode −2 V at time t2. At point 1303 in the without biased electrode the electric field driving the electrophoretic force is orders of magnitude weaker. Additionally, the direction alternates as the potential changes from +2 V at t1 to −2 V at t2, resulting in a time averaged electrophoretic induced velocity of 0.

In the case of the 1D electric field gradient plot representing the effect of the dielectrophoretic force, where positive DEP results in the particles moving towards regions of higher electric field gradient, a similar beneficial effect from the addition of a bias electrode is demonstrated. Consider a theoretical particle 6 microns from the substrate surface 1401. When the bias electrode is present at −40 V there is a relatively stronger dielectrophoretic force, due to higher electric field gradient, toward the substrate. The force direction towards the substrate under the with bias geometry is evidenced by the gradient of the electric field decreasing monotonically as the distance from the electrode increases, as positive DEP is a force towards areas of higher electric field gradient. The particle in the without electrode bias condition 1403 experiences a relatively weaker dielectrophoretic force due to the lower electric field gradient. Additionally, a positive dielectrophoretic force in the without bias scenario is directed away from the substrate at 6 μm distance as the electric field gradient increases moving away from the electrode at this location. Note that the gradient of the electric field also generally decreases with distance from the electrodes in the without-bias electrode case as well, so positive dielectrophoresis will still be successful. However, this may indicate that even when particles are close to the substrate the ability to capture them quickly and align them across electrodes with the dielectrophoretic effect may be further aided with the addition of the bias electrode.

### Materials and Methods

All patents, patent applications, provisional applications, and publications referred to or cited herein are incorporated by reference in their entirety, including all figures and tables, to the extent they are not inconsistent with the explicit teachings of this specification.

Following are examples that illustrate procedures for practicing the invention. These examples should not be construed as limiting. All percentages are by weight and all solvent mixture proportions are by volume unless otherwise noted.

EXAMPLE 1—Assembly of dense arrays of semiconducting carbon nanotubes. Consider a starting mixture of semiconducting and conducting carbon nanotubes synthesized off substrate with the aim to assemble them into a carbon nanotube field effect transistor (CNTFET) array. As the goal is to make contacts to the source and drain, the electrodes for assembly may be exposed. To form the substrate electrodes, a silicon wafer may be used as the substrate with through-silicon vias created via the Bosch DRIE process and electroplated with copper. Then redistribution layers may be created with the damascene process. The final electrodes prior to carbon nanotube assembly may comprise a planar layer of SiO₂ and copper electrodes flush with the surface of the SiO₂.

To establish a strong positive zeta potential on the carbon nanotubes to aid in dispersion and promote the electrophoretic force hydrogen ions can be established in the solution to be adsorbed onto the nanotube surface. This can be accomplished by the incorporation of a small amount of acetone and iodine into the solution. This generates hydrogen ions though the reaction.

C₃H₆O+I₂H+I—+C₃H₅IO

To aid in the separation of metallic and semiconducting nanowires an intermediate permittivity solution such as methanol may be chosen which is capable of forming a supercritical mixture with CO₂. At high AC signal frequencies semiconducting carbon nanotubes will experience a positive dielectrophoretic force according to equation Eq. 1 and metallic carbon nanotubes will experience a negative dielectrophoretic force. As the zeta potential for the nanotubes will be positive, the bias electrode will be kept at a positive bias with respect to the substrate electrodes and average potential of the AC electrodes patterned on the substrate.

First the carbon nanotubes will be suspended in a methanol solution with acetone and iodine. The solution will then be sonicated and stirred either before loading into the solution holding tank, or in some embodiments stirring and ultrasonics will be included into the holding tank. The wafer will be loaded into the wafer in contact with the AC electrical feedthroughs to the backside of the wafer. The CNT containing solution will be introduced by flowing through the solution inlet and out the solution loading outlet then all the valves to the chamber will close. The in-chamber pump will move solution over the wafer substrate. Bias potential and AC electric signal to the substrate electrodes will be supplied. This will cause semiconducting carbon nanoparticles to be moved toward the surface via the electrophoretic force and assembled across the electrodes via the dielectrophoretic force. Although metallic carbon nanoparticles will be similarly attracted toward the surface with the electrophoretic force at close range, they will be repelled by the dielectrophoretic force.

Once assembly is completed the solution will be drained to slightly above the wafer surface, pressurized CO₂ will be introduced, and the substrate will be heated to induce the liquid to supercritical phase transition without surface tension. Then the pressure will be released slowly inducing a supercritical to gas phase transition without surface tension. The remainder of the solution will be drained, and the wafer will be removed.

EXAMPLE 2—Plasmonic gold nanoparticle assembly. The assembly of gold nanoparticles may be of interest for wave guides and frequency shifting photonic elements. Frequency shifting may be desired if a detector manufacturer wants to make their photodetector more sensitive to frequencies different than the band gap of the material. In this case a compound semiconductor substrate with transparent ITO electrodes may be desired. As the gold is conductive to inhibit joule heating during assembly or electrical discharge a SiO₂ film may be coated over the surface of the electrodes and the electrodes may similarly be contacted from the substrate holder using through-substrate vias. Assembly will be performed in a method similar to the carbon nanotubes but at lower frequencies to attract the metallic nanoparticles. In this instance water may be used as the solvent with its pH adjusted to promote a strong zeta potential. Depending on the polarity of the zeta potential achieved the bias electrode may be biased positively or negatively.

The remainder of the assembly steps will be performed in a manner similar to the carbon nanotube assembly and the result will be plasmonic gold nanoparticles assembled over a compound semiconductor photodetector to shift the target wavelength of incoming light to a wavelength which can be detected more efficiently by the photodetector.

EXAMPLE 3—Crack free barium titanate thick film deposition. In some instances, thick crack free films may be desirable. Thicknesses of sputtered ferroelectric or ferromagnetic materials are limited by reasonable deposition times and coating of the sidewall of the sputtering chamber. For thick film deposition electrophoresis is a promising technique. However, for very thick films drying often causes issues with cracking due to the surface tension of the fluid. The environmentally controlled electrical assembly chamber described here can mitigate this surface tension problem. Barium titanate micro or nanoparticles may be first washed with dilute hydrochloric acid to remove their barium carbonate surface layer. Then when suspended in solution and flown over the substrate a bias potential between the substrate electrode and bias electrode will attract the barium titanate to the surface of the substrate forming a thick film. After deposition the solution may be drained to slightly above the substrate and supercritical drying may be induced similarly to the previous examples. However, due to the potential of the thick film to trap solution within it, multiple pressurization and depressurization steps may be required to fully dry the film. The lack of surface tension introduced by the supercritical drying process will result in a denser and crack free film than could otherwise be accomplished with traditional drying.

### EXEMPLIFIED EMBODIMENTS

The invention may be better understood by reference to certain illustrative examples, including but not limited to the following:

Embodiment 1. A nanoparticle assembly chamber 500 is configured to allow for introduction and draining of nano- or micro-particle solution from a tank 504 via pump 505, introduction of gas 501 compressed via compressor 502 to form a supercritical mixture with the particle containing solution outlet of the gas after a supercritical to gas phase transition to allow for supercritical drying with minimal to no surface tension disrupting assembly.

Embodiment 2. The particle assembly chamber 500 of embodiment 1 includes an electrical feedthrough to the bias electrode 508 and an electrical feedthrough 509 to the substrate electrodes, substrate heater, temperature sensors, level sensors, and internal pump.

Embodiment 3. The particle assembly chamber 500 of embodiment 2 includes an analog electronics rack 506 comprising a function generator, amplifier, and oscilloscope for controlling and monitoring the electrophoretic and dielectrophoretic forces driving assembly.

Embodiment 4. The particle assembly chamber 500 of embodiment 3 where the analog electronics 506, compressor 502, input and output gas pressure regulators 408, fluid pump 505 and liquid valves 401-403, are controlled via a PC or other digital control board 507.

Embodiment 5. The particle assembly chamber 500 of embodiment 1 includes the gas outlet that is terminated with a scrubber 503 to remove potential gaseous and particulate pollutants from the exhaust stream.

Embodiment 6. A particle assembly chamber 500 of embodiment 4 where during assembly an internal motor, pump, or impeller 412 moves particulate containing solution around the chamber 415 and between the substrate 413 and bias electrode 414.

Embodiment 7. A particle assembly chamber 500 of embodiment 6 where the bias electrode 105 is biased across the substrate 103 and substrate electrode 104 to create an electric field 106 across the bias electrode 105 and substrate 103 to induce an electrophoretic force depending upon the electrical properties of the suspended particles.

Embodiment 8. A particle assembly chamber 500 of embodiment 6 where alternating current electrodes 100 patterned on the substrate 103 induce regions of decreasing electric field gradient 101 from the electrodes 100. This electric field gradient induces a dielectrophoretic force towards 102 the electrodes depending upon the electrical properties of the suspended particles.

Embodiment 9. A particle assembly chamber 500 of embodiment 7 where a particle 201 suspended in the bulk solution experiences a drag force 206 from solution movement induced by the internal pump 205 and an electrophoretic force 207 towards the substrate region induced by the electric potential between the bias electrode 204 and the substrate and substrate electrode 203.

Embodiment 10. A particle assembly chamber 500 of embodiment 9, wherein the particle at a later time 301 when moved near the substrate experiences a polarization 304 due to the electric field gradient and is attracted toward the substrate electrodes with a positive dielectrophoretic force 305.

Embodiment 11. A particle assembly chamber 500 of embodiment 10, wherein assembly locations of the particles are maintained with supercritical drying to remove disruptive surface tension forces. Post assembly the nanoparticle containing solution is drained to a level slightly above the substrate 701, the chamber is pressurized and substrate 702 is heated creating a supercritical phase 704 above the substrate. As pressure is released slowly this phase is turned into a gaseous phase resulting in a gaseous phase down to a lower position 706 than the substrate height within the chamber and the remaining solution can be drained.

Embodiment 12. A particle assembly chamber 500 of embodiment 1 has an automated substrate loading and unloading system to increase throughput.

Embodiment 13. An environmentally controlled pressure chamber system for electrical assembly of particles onto a substrate, comprising:
a chamber;
an AC electrical feedthrough, through a wall of the chamber, configured to contact AC electrodes fabricated on a substrate;
a DC electrode located on a backside of the substrate and counter-electrode opposite the substrate;
a pump configured to induce particle-containing fluid to flow over the substrate;
an inlet and an outlet for a particle-containing solution; and
an inlet and an outlet for a compressed gas and supercritical fluid.

Embodiment 14. The pressure chamber system of embodiment 13, further comprising a valve-and-pump arrangement configured to automatically fill and drain the particle-containing solution.

Embodiment 15. The pressure chamber system of embodiment 13, wherein the compressed gas for creating the supercritical fluid is further pressurized with a compressor connected to the pressure chamber system.

Embodiment 16. The pressure chamber system of embodiment 13, wherein a pressure within the chamber system is precisely controlled with digital or analog input and output regulators.

Embodiment 17. The pressure chamber system of embodiment 13, further comprising one or more electric heaters and thermocouples to heat the substrate and the particle-containing solution to promote a supercritical phase change.

Embodiment 18. The pressure chamber system of embodiment 13, wherein the particles are moved over the substrate via drag force induced by the particle-containing solution being pumped over a surface of the substrate, wherein the particles being moved over the substrate are attracted to near the surface of the substrate from bulk of the particle-containing solution via an electrophoretic force induced on the particles via an electric potential across a bias electrode on the backside of the substrate and the counter-electrode above the substrate, and wherein the particles, when sufficiently close to the substrate, are forced and aligned across the AC electrodes patterned on the substrate via a positive dielectrophoretic force.

Embodiment 19. The pressure chamber system of embodiment 18, wherein once the particles are aligned across the electrodes, a level of the particle-containing solution is lowered by opening the chamber particle-containing solution outlet until a surface of the liquid solution is slightly above the surface of the substrate, wherein after the solution is lowered and particle-containing solution outlet is closed, a pressurized gas is pumped into the chamber via a compressor until a mixture of the pressurized gas and the particle-containing solution forms a supercritical fluid, wherein a resulting liquid-to-supercritical-fluid interface has no surface tension inhibiting disruption of particles after the assembly process during drying.

Embodiment 20. The pressure chamber system of embodiment 19, wherein formation of the supercritical fluid is additionally promoted through controlled heating of the substrate and/or chamber walls via inductive, resistive, joule heating, or heating through contact with a higher temperature medium.

Embodiment 21. The pressure chamber system of embodiment 20, wherein after the supercritical fluid is formed, the pressure is slowly released resulting in supercritical fluid to gas transition in a region above the surface of the substrate, wherein there is no surface tension between the supercritical fluid and the gas interface inhibiting the disruption of particles during the drying process, wherein the remaining fluid, if any, is drained in a region away from the wafer, and wherein after assembly is complete electric fields are turned off and the substrate is removed.

Embodiment 22. The pressure chamber system of embodiment 13, wherein during the assembly process, an average potential of the AC electrodes patterned on the substrate is connected with an electrical connection through the backside of the substrate, by a through substrate via, to a chuck to achieve lower particulate contamination compared to a top side connection.

Embodiment 23. The pressure chamber system of embodiment 13, wherein an average applied potential on the AC electrodes is equivalent to potential on the bias electrode on the backside of the wafer.

Embodiment 24. An environmentally controlled pressure chamber system for electrical assembly of particles onto a substrate, comprising:
a chamber;
an AC electrical feedthrough, through a wall of the chamber, configured to contact AC electrodes fabricated on a substrate;
a pump configured to induce particle-containing fluid to flow over the substrate;
inlet and outlet for particle-containing solution; and
inlet and outlet for compressed gas and supercritical fluid.

Embodiment 25. The pressure chamber system of embodiment 24, further comprising a valve-and-pump arrangement configured to automatically fill and drain the particle-containing solution.

Embodiment 26. The pressure chamber system of embodiment 24, wherein the compressed gas for creating the supercritical fluid is further pressurized with a compressor connected to the chamber.

Embodiment 27. The pressure chamber system of embodiment 24, wherein a pressure within the chamber is precisely controlled with digital or analog input and output regulators.

Embodiment 28. An environmentally controlled pressure chamber system for electrical assembly of particles onto a substrate, comprising:
a chamber;
an DC electrical feedthrough, through a wall of the chamber, configured to contact DC electrodes fabricated onto a substrate or located on a backside of the substrate;
a DC electrode located on the backside of the substrate and counter-electrode opposite the substrate; and
a pump configured to induce particle-containing fluid to flow over the substrate;
inlet and outlet for particle-containing solution; and
inlet and outlet for compressed gas and supercritical fluid.

Embodiment 29. The pressure chamber system of embodiment 28, further comprising a valve-and-pump arrangement configured to automatically fill and drain the particle-containing solution.

Embodiment 30. The pressure chamber system of embodiment 28, wherein the compressed gas for creating the supercritical fluid is further pressurized with a compressor connected to the chamber.

Embodiment 31. The pressure chamber system of embodiment 28, wherein a pressure within the chamber is precisely controlled with digital or analog input and output regulators.

Embodiment 32. The pressure chamber system of embodiment 28, wherein particles are introduced into the chamber, forming a film through electrophoretic deposition onto the substrate, and wherein supercritical drying is configured to form a dense crack free film by eliminating surface tension.

Although the present invention has been illustrated and described herein with reference to preferred embodiments and specific examples thereof, it will be readily apparent to those of ordinary skill in the art that other embodiments and examples may perform similar functions and/or achieve like results.

It should be understood that the examples and embodiments described herein are for illustrative purposes only and that various modifications or changes in light thereof will be suggested to persons skilled in the art and are to be included within the spirit and purview of this application and the scope of the appended claims. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

### REFERENCES

1. IEEE Heterogeneous Integration Roadmap, 2023 ed., ch. 16. Emerging Research Devices. https://eps.ieee.org/images/files/HIR_2023/ch16_devices.pdf, 1-2, 41.
2. IRDS 2022: Beyond CMOS and Emerging Research Materials—IEEE IRDS. https://irds.ieee.org/images/files/pdf/2022/2022IRDS_BC.pdf, 21-22.
3. US20220109244A1
4. U.S. Pat. No. 10,892,399B2
5. U.S. Pat. No. 11,271,160B2
6. US20050077468A1
7. KR101759539B1
8. KR20070050333A
9. U.S. Pat. No. 11,466,169B2

We claim:

1. An environmentally controlled pressure chamber system for electrical assembly of particles onto a substrate, comprising:
a chamber;
an AC electrical feedthrough, through a wall of the chamber, configured to contact AC electrodes fabricated on a substrate;
a DC electrode located on a backside of the substrate and counter-electrode opposite the substrate;
a pump configured to induce particle-containing fluid to flow over the substrate;
an inlet and an outlet for a particle-containing solution; and
an inlet and an outlet for a compressed gas and supercritical fluid.

2. The pressure chamber system of claim 1, further comprising a valve-and-pump arrangement configured to automatically fill and drain the particle-containing solution.

3. The pressure chamber system of claim 1, wherein the compressed gas for creating the supercritical fluid is further pressurized with a compressor connected to the pressure chamber system.

4. The pressure chamber system of claim 1, wherein a pressure within the chamber system is precisely controlled with digital or analog input and output regulators.

5. The pressure chamber system of claim 1, further comprising one or more electric heaters and thermocouples to heat the substrate and the particle-containing solution to promote a supercritical phase change.

6. The pressure chamber system of claim 1, wherein the particles are moved over the substrate via drag force induced by the particle-containing solution being pumped over a surface of the substrate, wherein the particles being moved over the substrate are attracted to near the surface of the substrate from bulk of the particle-containing solution via an electrophoretic force induced on the particles via an electric potential across a bias electrode on the backside of the substrate and the counter-electrode above the substrate, and wherein the particles, when sufficiently close to the substrate, are forced and aligned across the AC electrodes patterned on the substrate via a positive dielectrophoretic force.

7. The pressure chamber system of claim 6, wherein once the particles are aligned across the electrodes, a level of the particle-containing solution is lowered by opening the chamber particle-containing solution outlet until a surface of the liquid solution is slightly above the surface of the substrate, wherein after the solution is lowered and particle-containing solution outlet is closed, a pressurized gas is pumped into the chamber via a compressor until a mixture of the pressurized gas and the particle-containing solution forms a supercritical fluid, wherein a resulting liquid-to-supercritical-fluid interface has no surface tension inhibiting disruption of particles after the assembly process during drying.

8. The pressure chamber system of claim 7, wherein formation of the supercritical fluid is additionally promoted through controlled heating of the substrate and/or chamber walls via inductive, resistive, joule heating, or heating through contact with a higher temperature medium.

9. The pressure chamber system of claim 8, wherein after the supercritical fluid is formed, the pressure is slowly released resulting in supercritical fluid to gas transition in a region above the surface of the substrate, wherein there is no surface tension between the supercritical fluid and the gas interface inhibiting the disruption of particles during the drying process, wherein the remaining fluid, if any, is drained in a region away from the wafer, and wherein after assembly is complete electric fields are turned off and the substrate is removed.

10. The pressure chamber system of claim 1, wherein during the assembly process, an average potential of the AC electrodes patterned on the substrate is connected with an electrical connection through the backside of the substrate, by a through substrate via, to a chuck to achieve lower particulate contamination compared to a top side connection.

11. The pressure chamber system of claim 1, wherein an average applied potential on the AC electrodes is equivalent to potential on the bias electrode on the backside of the wafer.

12. An environmentally controlled pressure chamber system for electrical assembly of particles onto a substrate, comprising:
a chamber;
an AC electrical feedthrough, through a wall of the chamber, configured to contact AC electrodes fabricated on a substrate;
a pump configured to induce particle-containing fluid to flow over the substrate;
inlet and outlet for particle-containing solution; and
inlet and outlet for compressed gas and supercritical fluid.

13. The pressure chamber system of claim 12, further comprising a valve-and-pump arrangement configured to automatically fill and drain the particle-containing solution.

14. The pressure chamber system of claim 12, wherein the compressed gas for creating the supercritical fluid is further pressurized with a compressor connected to the chamber.

15. The pressure chamber system of claim 12, wherein a pressure within the chamber is precisely controlled with digital or analog input and output regulators.

16. An environmentally controlled pressure chamber system for electrical assembly of particles onto a substrate, comprising:
a chamber;
an DC electrical feedthrough, through a wall of the chamber, configured to contact DC electrodes fabricated onto a substrate or located on a backside of the substrate;
a DC electrode located on the backside of the substrate and counter-electrode opposite the substrate; and
a pump configured to induce particle-containing fluid to flow over the substrate;
inlet and outlet for particle-containing solution; and
inlet and outlet for compressed gas and supercritical fluid.

17. The pressure chamber system of claim 16, further comprising a valve-and-pump arrangement configured to automatically fill and drain the particle-containing solution.

18. The pressure chamber system of claim 16, wherein the compressed gas for creating the supercritical fluid is further pressurized with a compressor connected to the chamber.

19. The pressure chamber system of claim 16, wherein a pressure within the chamber is precisely controlled with digital or analog input and output regulators.

20. The pressure chamber system of claim 16, wherein particles are introduced into the chamber, forming a film through electrophoretic deposition onto the substrate, and wherein supercritical drying is configured to form a dense crack free film by eliminating surface tension.
